(19) United States
(12) Patent Application Publication
(10) Pub. No.: US 2008/0213998 A1
(43) Pub. Date: Sep. 4, 2008

(54) METHOD FOR MANUFACTURING SEMICONDUCTOR DEVICE, SEMICONDUCTOR MANUFACTURING APPARATUS AND STORAGE MEDIUM FOR EXECUTING THE METHOD

(75) Inventors: Hiroyuki Nagai, Yamanashi (JP); Hidenori Miyoshi, Yamanashi (JP); Kaoru Maekawa, Tokyo (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/040,256

(22) Filed: Feb. 29, 2008

(30) Foreign Application Priority Data
Mar. 2, 2007 (JP) 2007-053178

(51) Int. Cl. H01L 21/44; C23C 16/00

(52) U.S. Cl. 438/653; 118/725; 257/E21.476

(57) ABSTRACT

The semiconductor device manufacturing method includes forming an alloy film of copper and an additive metal along a wall surface of a recess portion of an interlayer insulating film in a surface of a substrate; forming a barrier layer made of a compound of the additive metal and a constituent element of the interlayer insulating film; heating the substrate under an atmosphere containing an organic acid, an organic acid anhydride, or ketones to precipitate surplus additive metal onto a surface of the alloy film; and burying copper in the recess portion after heating the substrate. Since the organic acid, the organic acid anhydride, and the ketones have a reducing power for Cu, an oxidation of Cu in the alloy film is suppressed while a barrier layer made of a compound of the additive metal and a constituent element of the insulating film is formed.

### FIELD OF THE INVENTION

The present disclosure relates to a semiconductor device manufacturing method and a semiconductor manufacturing apparatus for forming a copper wiring by way of forming a recess in an insulating film and filling the recess with copper and a storage medium storing therein a computer executable control program for executing the method.

### BACKGROUND OF THE INVENTION

A multi-layered wiring structure of a semiconductor device is formed by burying a metal wiring in an interlayer insulating film. Copper (Cu) has been used as a material for the metal wiring, for it has a small electro-migration tendency and a low resistance property. For a formation process of a Cu wiring, a damascene process has been generally employed.

The damascene process involves the steps of forming trenches for accommodating therein wirings buried in the interlayer insulating film; forming via holes for accommodating therein connection wirings which connect upper and lower wirings; and filling such recesses with Cu by a CVD (Chemical Vapor Deposition) method, an electroplating method, or the like. When the CVD method is employed, a very thin Cu seed layer needs to be formed along the inner surfaces of the recesses to facilitate the burial of Cu. Likewise, when the electroplating method is used, the formation of a Cu seed layer is also required to use it as an electrode. Further, since Cu is highly likely to be diffused into the insulating film, a barrier film made of, for example, a laminated body of Ta/TaN needs to be formed on the recesses. Accordingly, the barrier film and the Cu seed film are formed on the surfaces of the recesses by, for example, a sputtering method.

Meanwhile, with the progression of miniaturization of wiring patterns, the barrier film and the seed layer, which are formed separately, are both required to have further reduced thicknesses. With a conventional barrier film fabrication method, however, it has been difficult to form a barrier film with high uniformity. Furthermore, the barrier film formed by the conventional method has problems in the aspect of reliability of its barrier property as well as in the aspect of interface adhesiveness to the seed layer, or the like.

In consideration of the mentioned problems, Patent Reference 1 discloses a method of forming a barrier film by forming an alloy film of Cu and an additive metal, for example, Mn (manganese), along a surface of a recess in an insulating film and then performing an annealing process. To be specific, Mn in the alloy is separated from Cu by the annealing process. Some of the Mn is diffused into a surface portion of the interlayer insulating film to react with 0 or Si, which is a constituent element of the interlayer insulating film. As a result, a barrier film of, for example, a MnOₓ oxide (x is a natural number) or a MnSiₓO_{y} oxide (x and y are natural numbers), which is a very stable compound, is formed in a self-aligning manner. Further, some of the Mn moves toward a surface side of the alloy film (opposite from the interlayer insulating film) so that a Cu film serving as a seed layer is formed. This self-formed barrier film is uniform and very thin, thereby contributing to solving the above-mentioned problems.

However, Patent Reference 1 does not specify in which atmosphere the annealing process should be carried out after the alloy film is formed on the surface of the recess. Further, though an annealing process is described in the Patent Reference 1 to be performed under an oxygen-containing atmosphere after burying the copper, such annealing process allow the alloy film and the buried Cu to be oxidized, thereby raising a likelihood of increase in wiring resistivity and decrease in yield.

[Patent Reference 1]

Japanese Patent Laid-open Application No. 2005-277390: (paragraphs [0018]˜[0020], paragraphs [0042]˜[0044], FIGS. 1 and 7, and so forth)

### BRIEF SUMMARY OF THE INVENTION

In view of the foregoing, the present disclosure provides a semiconductor device manufacturing method and a semiconductor manufacturing apparatus, in case of forming a barrier film and a copper film by using an alloy film of copper and an additive metal formed along recesses of an insulating film and then burying a copper wiring, capable of inhibiting an oxidation of the copper film and also suppressing an increase of a wiring resistance. Further, the present disclosure also provides a storage medium storing therein a program for executing the manufacturing method.

In accordance with a first aspect of the present invention, there is provided a method for manufacturing a semiconductor device, including: forming an alloy film of copper and an additive metal along a wall surface of a recess portion of an interlayer insulating film in a surface of a substrate; forming a barrier layer made of a compound of the additive metal and a constituent element of the interlayer insulating film; heating the substrate under an atmosphere containing an organic acid, an organic acid anhydride, or ketones to precipitate surplus additive metal onto a surface of the alloy film; and burying copper in the recess portion after heating the substrate. Further, the alloy film includes a laminated film of a copper film and an additive metal film.

The manufacturing method may further include, for example, removing the surplus additive metal precipitated on the surface of the alloy film after heating the substrate and before burying the copper. In addition, the additive metal may be selected from, for example, Mn, Ti, Al, Nb, Cr, V, Y, Tc and Re.

The organic acid may be, for example, a carboxylic acid and, in this case, for example, a formic acid. The organic acid anhydride may be, for example, a carboxylic acid anhydride and, in this case, for example, an acetic anhydride. In the step of heating the substrate, the substrate is heated up to, for example, about 20° C. to 500° C., and more desirably, about 400° C. to 500° C.

In accordance with a second aspect of the present invention, there is provided a semiconductor manufacturing apparatus including: a first processing vessel having therein a first mounting table for mounting thereon a substrate in a surface of which an interlayer insulating film provided with a recess portion is formed; a film forming unit having an alloy film forming mechanism for forming an alloy film of copper and an additive metal along a wall surface of the recess portion; a second processing vessel having therein a second mounting table for mounting thereon the substrate; an atmosphere generating unit for generating an atmosphere containing an organic acid, an organic acid anhydride, or ketones in the second processing vessel; a heating process unit having a heating mechanism for heating the substrate mounted on the second mounting table; and a substrate transfer mechanism for transferring the substrate between the film forming unit and the heating process unit.

The semiconductor manufacturing apparatus may further include: a loader module, connected to a carrier accommodating the substrate therein, for performing loading and unloading of the substrate in the carrier; and a transfer chamber under a vacuum atmosphere, for accommodating the substrate loaded via the loader module, wherein the first processing vessel and the second processing vessel may be airtightly coupled to the transfer chamber, and the transfer mechanism may be provided in the transfer chamber. Further, the transfer of the substrate between the film forming unit and the heating process unit may be carried out, for example, under an atmospheric atmosphere.

In accordance with a third aspect of the present invention, there is provided a storage medium which is used in a semiconductor manufacturing apparatus for performing a process on a substrate and stores therein a computer executable computer program, wherein the computer program includes step groups for executing the above-mentioned manufacturing method of the semiconductor device.

The present disclosure performs a heating process on an alloy film of Cu and an additive metal formed along a surface of a recess portion of an insulating film in an atmosphere containing an organic acid, an organic acid anhydride, or ketones. Since the organic acid, the organic acid anhydride, and the ketones have a reducing power for Cu, an oxidation of Cu in the alloy film is suppressed while a barrier layer made of a compound of the additive metal and a constituent element of the insulating film is formed. Further, the additive metal can be precipitated on a surface of the alloy film. As a result, an increase of wiring resistivity can be suppressed when the wiring is formed by filling Cu in the recess portion, and also a decrease in a yield rate of a semiconductor device, which is formed by using this wiring, can be suppressed.

### BRIEF DESCRIPTION OF THE DRAWINGS

The disclosure may best be understood by reference to the following description taken in conjunction with the following figures:

FIG. 1 is a configuration view of a substrate processing system including a semiconductor manufacturing apparatus in accordance with an embodiment of the present invention;

FIG. 2 sets forth a configuration view of the semiconductor manufacturing apparatus;

FIG. 3 presents a longitudinal cross sectional view of a CuMn sputtering module incorporated in the semiconductor manufacturing apparatus;

FIG. 4 depicts a longitudinal cross sectional view of a formic acid processing module incorporated in the semiconductor manufacturing apparatus;

FIGS. 5A to 5F provide cross sectional views to describe a process sequence of forming a wiring by using the substrate processing system;

FIGS. 6A to 6D offer cross sectional views to describe a process sequence in which films of Mn are formed by an annealing process in the course of forming the wiring;

FIG. 7 is an example of configuration of another substrate processing system;

FIG. 8 illustrates an example of configuration of another semiconductor manufacturing apparatus;

FIGS. 9A to 9C provide cross sectional views to describe an example of another process sequence of a wiring formation;

FIG. 10 presents a graph to describe a movement of Mn in a CuMn film due to an annealing process performed by using a formic acid;

FIG. 11 is a graph showing a test result of investigating a movement of Mn while varying an annealing temperature;

FIG. 12 sets forth a graph showing a test result of investigating a movement of Mn while varying a pressure during an annealing;

FIG. 13 depicts a graph showing a movement of Mn in a CuMn film due to an annealing process performed by using an acetic anhydride; and

FIG. 14 offers a graph showing a movement of Mn in a CuMn film due to an annealing process performed by using a nitrogen gas.

### DETAILED DESCRIPTION OF THE INVENTION

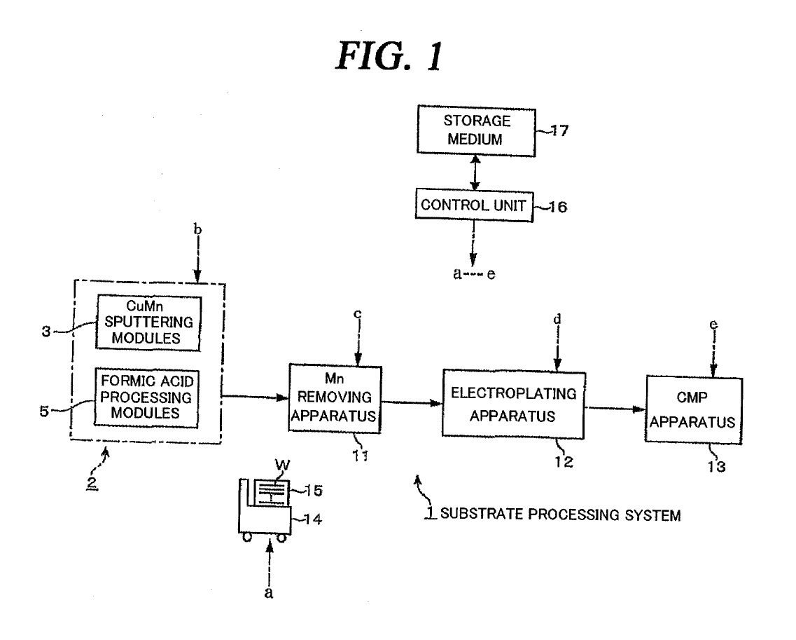

First, a substrate processing system 1 in a clean room including a semiconductor manufacturing apparatus in accordance with an embodiment of the present invention will be described with reference to FIG. 1. The substrate processing system 1, which will be described in detail later, is a system for forming a wiring on a surface of a semiconductor wafer W (hereinafter, referred to as a wafer), i.e., a substrate. In FIG. 1, a reference numeral 2 denotes an example of a semiconductor manufacturing apparatus in accordance with an embodiment of the present invention. The semiconductor manufacturing apparatus 2 has a multi-chamber system and performs a desired process on the wafer W under a vacuum atmosphere. The semiconductor manufacturing apparatus 2 includes CuMn sputtering modules 3 for forming a film of an alloy of Cu and an additive metal Mn on the wafer W; and formic acid processing modules 5 for forming a self-formed barrier film by annealing the wafer W having the CuMn alloy film under a formic acid atmosphere. A configuration of the semiconductor manufacturing apparatus 2 will be explained in further detail later.

In FIG. 1, a reference numeral 11 is a Mn removing apparatus which performs a wet cleaning process for removing Mn on the surface of the wafer W by way of submerging the wafer W in a solution, for example, a hydrochloric acid, capable of dissolving Mn. Further, a reference numeral 12 is an electroplating apparatus which forms on the wafer W a Cu film which constitutes a wiring. A reference numeral 13 is a CMP (Chemical Mechanical Polishing) apparatus.

In FIG. 1, a reference numeral 14 is an automatic transfer robot which conveys a carrier 15 accommodating a plurality of, for example, 25 wafers W, in the clean room. As indicated by arrows in FIG. 1, the automatic transfer robot 14 transfers the carrier 15 to the semiconductor manufacturing apparatus 2, to the Mn removing apparatus 11, to the electroplating apparatus 12 and then to the CMP apparatus 13 in this sequence. The carrier 15 is referred to as a FOUP (Front Opening Unified Pod) configured as an air-tightly sealed carrier whose inside is kept, for example, under an atmospheric atmosphere.

Each apparatus of the substrate processing system 1 includes a subordinate computer for controlling an operation of the apparatus, and the substrate processing system 1 has a host computer, which constitutes a part of a control unit 16, for controlling each subordinate computer. The control unit 16 incorporates a data processing module made up of a program, a memory, a CPU, and so forth. The program stored in the host computer is a transfer sequence program for executing a transfer of the carrier 15 between the individual apparatuses. Further, the individual subordinate computers include programs for carrying out the aforementioned processes on the wafers W in the carrier 15 and for forming wiring portions, which will be descried later, on the wafers W.

As indicated by notations a to e in FIG. 1, the control unit 16 transmits a control signal to each apparatus of the substrate processing system 1 by the program stored in the host computer, and, in response to the control signal, the subordinate computer of the individual apparatus controls each constituent component thereof. The program is stored in a storage medium 17 made up of, for example, a flexible disk, a compact disk, a MO (magneto-optical) disk, or the like to be installed in the control unit 16.

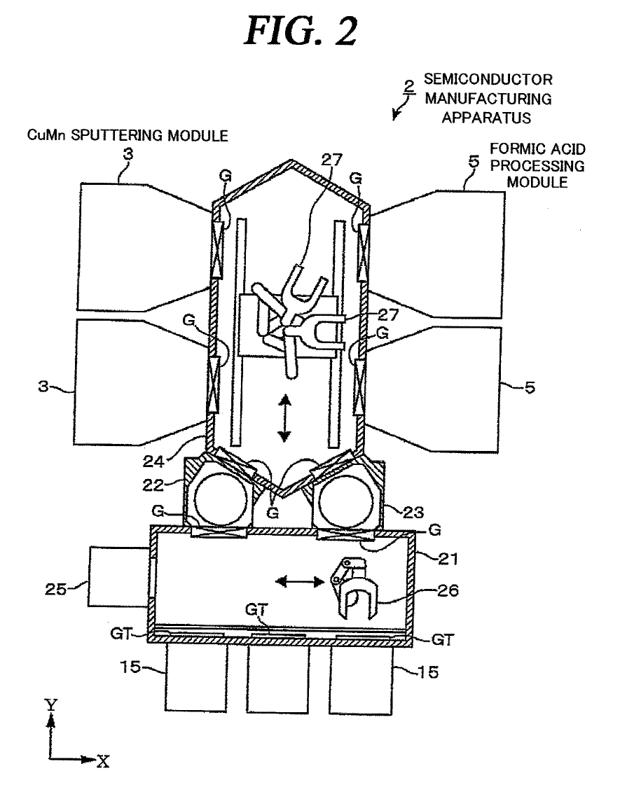

Now, a detailed configuration of the semiconductor manufacturing apparatus 2 will be explained with reference to FIG. 2. The semiconductor manufacturing apparatus 2 includes a first transfer chamber 21 which constitutes a loader module for performing loading and unloading of a substrate; load lock chambers 22 and 23; and a second transfer chamber 24 serving as a vacuum transfer chamber module. The first transfer chamber 21 has, on a front wall thereof, gate doors GT connected to the sealed carriers 15 and opened or closed along with lids of the carriers 15. The CuMn sputtering modules 3 and the formic acid processing modules 5 are airtightly connected to the second transfer chamber 24.

Further, an alignment chamber 25 is provided on a lateral side of the first transfer chamber 21. Each of the load lock chambers 22 and 23 includes a vacuum pump and a leak valve (not shown), and the insides of the load lock chambers 22 and 23 can be switched between an atmospheric atmosphere and a vacuum atmosphere. That is, since the first transfer chamber 21 and the second transfer chamber 24 are kept under the atmospheric atmosphere and the vacuum atmosphere, respectively, the load lock chambers 22 and 23 serve to adjust the atmosphere for the transfer of the wafer W between the first and second transfer chambers 21 and 24. Further, a notation G in FIG. 2 indicates gate valves (partition valves) which separate the load lock chambers 22, 23 from the first or the second transfer chamber 21 or 24, and separate the second transfer chamber 24 from the modules 3 or 5.

The first and second transfer chambers 21 and 24 include a first transfer mechanism 26 and a second transfer mechanism 27, respectively. The first transfer mechanism 26 is a transfer arm for carrying out a transfer of the wafer W between the carrier 15 and the load lock chamber 22 or 23 and between the first transfer chamber 21 and the alignment chamber 25. The second transfer mechanism 27 is a transfer arm for carrying out a transfer of the wafer W between the load lock chamber 22 or 23 and the CuMn sputtering modules 3 or the formic acid processing modules 5.

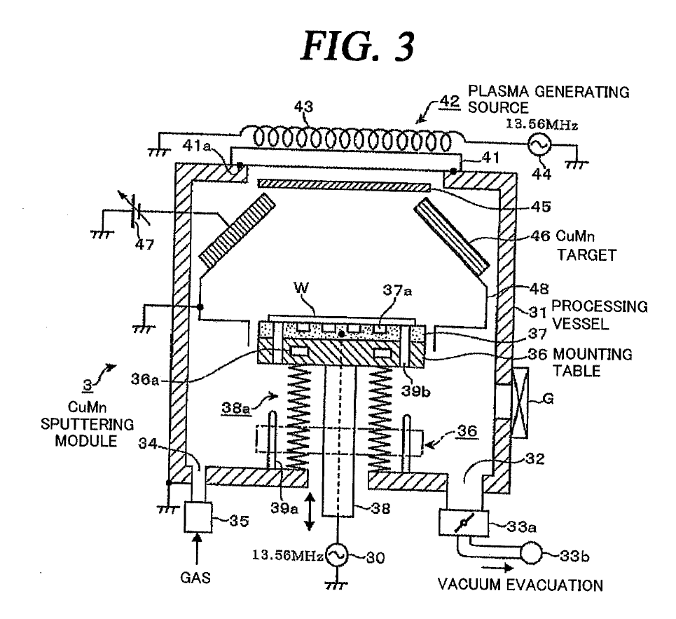

Below, a configuration of each CuMn sputtering module 3 included in the semiconductor manufacturing apparatus 2 will be described in conjunction with FIG. 3. The sputtering module 3 is referred to as an ICP (Inductively Coupled Plasma) type plasma sputtering module, and it includes a cylindrical processing vessel 31 made of, for example, aluminum (Al). The processing vessel 31 is grounded, and a gas exhaust port 32 is provided at a bottom portion of the processing vessel 31. The inside of the processing vessel 31 is evacuated to a specific vacuum level by a vacuum pump 33b via a throttle valve 33a. Further, a gas inlet port 34, for example, is provided at a bottom portion of the processing vessel 31 to serve as a gas introduction mechanism for introducing a necessary gas into the processing vessel 31. A plasma gas, for example, an Ar gas, and other necessary gases are supplied from the gas inlet port 34 via a gas control unit 35 which is made up of a gas flow controller, a valve, and so forth.

A mounting table 36 made of, for example, Al is disposed in the processing vessel 31, and an electrostatic chuck 37 for attracting and holding the wafer W is provided on a top surface of the mounting table 36. A reference numeral 37a denotes a flow path for a thermally conductive gas which enhances thermal conductivity of the wafer W and the mounting table 36. Further, a reference numeral 36a is a circulation path through which a coolant for cooling the wafer W flows. The coolant is supplied and exhausted through a flow path (not shown) inside a supporting column 38 which sustains the mounting table 36. The supporting column 38 is movable up and down by an elevating mechanism (not shown), whereby the mounting table 36 can be lifted up and lowered down. A reference numeral 38a denotes an expansible/contractible bellows surrounding the supporting column 38. The bellows 38a allows the mounting table 36 to be moved up and down while maintaining airtightness of the inside of the processing vessel 31. A reference numeral 39a denotes three supporting pins (though only two of them are shown in FIG. 3). Further, a reference numeral 39b denotes pin insertion holes corresponding to the supporting pins 39a. When the mounting table 36 is lowered, the wafer W is transferred between the supporting pins 39a and the second transfer mechanism 27. Further, a high frequency power supply 30 for generating a high frequency power of, for example, about 13.56 MHz is connected to the electrostatic chuck 37, and a specific bias voltage can be applied to the mounting table 36.

Provided at a ceiling portion of the processing vessel 31 via a seal member 41a such as an O ring is a transmission plate 41 which transmits a high frequency wave and is formed of, for example, a dielectric such as aluminum nitride. A reference numeral 42 denotes a plasma generating source which generates a plasma by converting, for example, an Ar gas, which is supplied into a processing space inside the processing vessel 31, into the plasma. To elaborate, the plasma generating source 42 includes an induction coil 43 provided to correspond to the transmission plate 41, and a high frequency power supply 44 of a frequency of, for example, 13.56 MHz for plasma generation is connected to the induction coil 43. A high frequency wave from the high frequency power supply 44 is introduced into the processing space via the transmission plate 41.

Disposed directly under the transmission plate 41 is a baffle plate 45 made of, for example, Al, and it serves to diffuse the high frequency wave. Further, an annular CuMn target 46 having, for example, an inwardly-inclined cross section is disposed below the baffle plate 45 so as to surround an upper region of the processing space. The target 46 is made of a Cu alloy containing Mn, and the content of the Mn ranges from, for example, about 1 atomic percent to 30 atomic percent. A variable DC power supply 47 is coupled to the CuMn target 46, and a cylindrical protection cover 48 is provided below the CuMn target 46 to surround the processing space, wherein the protection cover 38 is made of, for example, Al and is grounded.

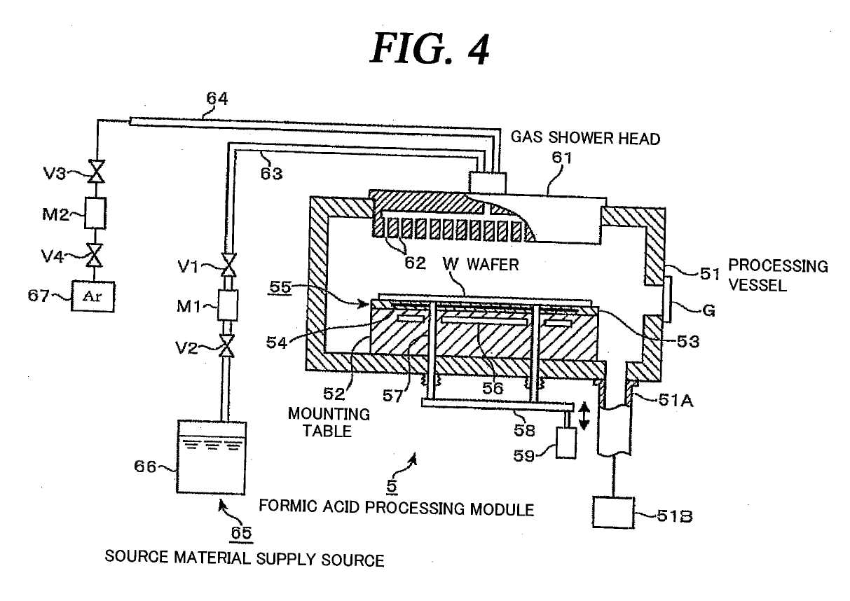

Now, a configuration of each formic acid processing module 5 incorporated in the semiconductor manufacturing apparatus 2 will be described with reference to FIG. 4. A reference numeral 51 in FIG. 4 is a processing vessel configured as a vacuum chamber made of, for example, Al. Disposed in a bottom portion of the processing vessel 51 is a mounting table 52 for mounting a wafer W thereon. An electrostatic chuck 55 formed by embedding a chuck electrode 54 in a dielectric layer 53 is provided on a top surface portion of the mounting table 52, and a chuck voltage is applied to the electrostatic chuck 55 from a power supply unit (not shown).

Further, a heater 56 is provided inside the mounting table 52 to heat the wafer W placed on the electrostatic chuck 55 up to a specific temperature level. The mounting table 52 is also provided with supporting pins 57 configured to be protrusible above and retractable below a mounting surface, wherein the supporting pins 57 serve to lift and lower the wafer W, allowing a transfer of the wafer W to be carried out with respect to the second transfer mechanism 27. The supporting pins 57 are connected to a driving unit 59 via a supporting member 58, and are moved up and down by operating the driving unit 59.

A gas shower head 61 is disposed at a ceiling portion of the processing vessel 51 to face the mounting table 52. The gas shower head 61 is provided with a number of gas supply holes 62 in its lower surface. Connected to the gas shower head 61 are a first gas supply line 63 for supplying a source gas and a second gas supply line 64 for supplying a dilution gas. The source gas and the dilution gas supplied from the gas supply lines 63 and 64 are mixed together, and this gaseous mixture is supplied into the processing vessel 51 through the gas supply holes 62.

The first gas supply line 63 is connected to a source material supply source 65 via a valve V1, a mass flow controller M1 serving as a gas flow rate controller and a valve V2. The source material supply source 65 includes a reservoir 66 made of stainless steel, and a carboxylic acid as an organic acid, for example, a formic acid, having a reducing power for Cu is stored in the reservoir 66. Further, the second gas supply line 64 is coupled to a dilution gas supply source 67 for supplying the dilution gas, for example, Ar (argon) gas, via a valve V3, a mass flow controller M2 and a valve V4.

One end of a gas exhaust pipe 51A is connected to a bottom portion of the processing vessel 51, and the other end of the gas exhaust pipe 51A is coupled to a vacuum pump 51B serving as a vacuum evacuation unit. With this configuration, the interior of the processing vessel can be maintained at a preset pressure level during a formic acid process.

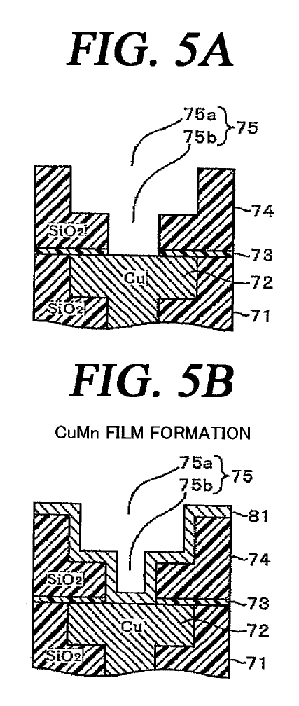

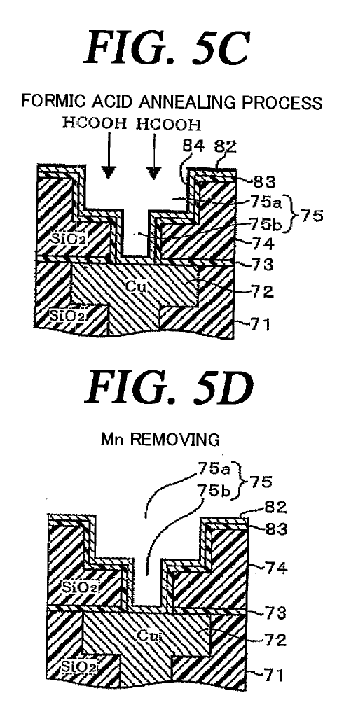

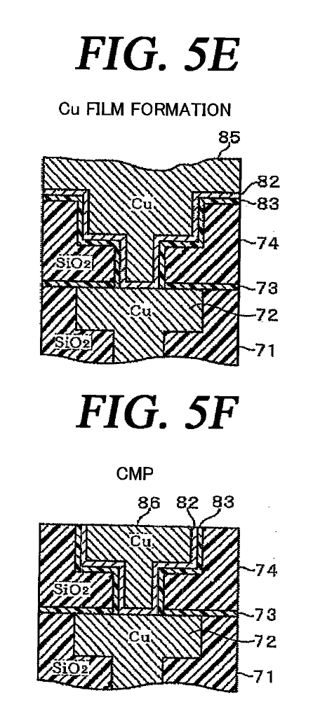

Now, a wafer W processed by the above-described substrate processing system 1 will be explained in connection with FIG. 5A. Before the wafer W is transferred to this substrate processing system, an underlayer wiring 72 is formed in the surface of the wafer W by burying Cu in an interlayer insulating film 71 made of SiO₂ (silicon oxide), and an interlayer insulating film 74 is laminated on the interlayer insulting film 71 via a barrier film 73. Further, a recess portion 75 including a trench 75a and a via hole 75b is formed in the interlayer insulating film 74, and the underlayer wiring 72 is exposed to the recess portion 75. A process to be described below is a process for forming an upper wiring electrically connected with the underlayer wiring 72 by burying Cu in the recess portion 75. Until now, though the interlayer insulating films have been exemplified by the SiO₂ films, a SiOCH film or the like can be employed as well.

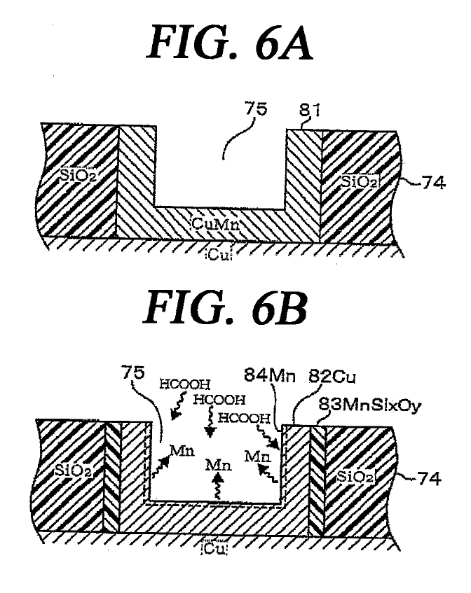

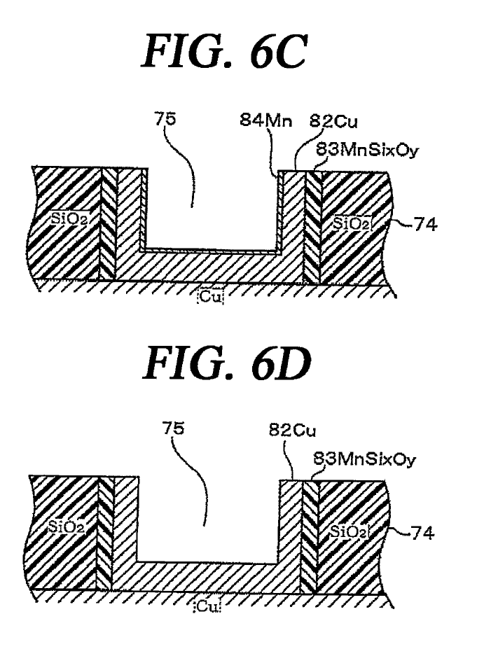

Hereinafter, a semiconductor manufacturing process will be described with reference to FIGS. 5A to 6D. FIGS. 5A to 5F illustrate cross sectional views to describe a manufacturing process of a semiconductor device formed in a surface portion of the wafer W. FIGS. 6A to 6D illustrate changes in the recess portion 75 when a wafer W is processed by each apparatus in the substrate processing system. In FIGS. 6A to 6D, the structure of the recess portion 75 is simplified to focus on the changes.

First, a carrier 15 is transferred to the semiconductor manufacturing apparatus 2 by the transfer robot 14 and is connected to the first transfer chamber 21. Then, the gate door GT and the lid of the carrier 15 are opened simultaneously, and a wafer W in the carrier 15 is loaded into the first transfer chamber 21 by the first transfer mechanism 26. Thereafter, the wafer W is conveyed into the alignment chamber 25, and the direction or the eccentricity of the wafer W is controlled therein. Then, the wafer W is transferred into the load lock chamber 22 (or 23). Once the internal pressure of the load lock chamber 22 is adjusted, the wafer W is conveyed into the second transfer chamber 24 from the load lock chamber 22 by the second transfer mechanism 27. Subsequently, a gate valve G of one of the CuMn sputtering modules 3 is opened, and the wafer W is loaded into the CuMn sputtering module 3 by the second transfer mechanism 27.

After the wafer W is loaded into the processing vessel 31 of the CuMn sputtering module 3 and placed on the electrostatic chuck 37 on the mounting table 36, the mounting table 36 is moved up to a preset position, and the gate valve G is closed and the processing vessel 31 is evacuated to vacuum by the vacuum pump 33b. Then, an Ar gas is supplied into the processing vessel 31 by the operation of the gas control unit 35. Subsequently, a DC power is supplied to the CuMn target 46 from the variable DC power supply 47, and a high frequency power is supplied to the induction coil 43 from the high frequency power supply 44. Further, a preset bias voltage is applied to the mounting table 36.

By supplying the powers to the CuMn target 46 and the induction coil 43, an Ar plasma containing Ar ions therein is generated in the processing space. The Ar ions collide with the CuMn target 46, whereby the CuMn target 46 is sputtered. Cu atoms (Cu atom groups) and Mn atoms (Mn atom groups) of the sputtered CuMn target 46 are ionized when they pass through the plasma. The ionized Cu atoms (Cu atom groups) and Mn atoms (Mn atom groups) are attracted toward the mounting table 36 by the bias voltage applied to the mounting table 36, and are deposited on the wafer W on the mounting table 36. Consequently, as shown in FIGS. 5A and 5B, a CuMn film 81, i.e., an alloy film of Cu and Mn, is formed, and the inside of the recess portion 75 is covered with the CuMn film 81 (see FIG. 6A). The thickness of the CuMn film 81 ranges from, for example, about 3 nm to 100 nm.

After the formation of the CuMn film 81 is carried out, the supply of the DC power to the CuMn target 46 and the supply of the high frequency powers to the induction coil 43 and the mounting table 36 are stopped, and the supply of the Ar gas is also ceased. Thereafter, the mounting table 36 is lowered and the gate valve G is opened, and the wafer W is conveyed onto the second transfer mechanism 27. Subsequently, a gate valve G of one of the formic acid processing modules 5 is opened, and the wafer W is conveyed into the processing vessel 51 inside the formic acid processing module 5 by the second transfer mechanism 27.

After the wafer W is loaded into the processing vessel 51 of the formic acid processing module 5 and is finally placed on the electrostatic chuck 55 on the mounting table 52, the gate valve G is closed, and then the processing vessel 51 is evacuated to vacuum by the vacuum pump 51B. Further, the wafer W is heated by the heater 56 of the mounting table 52, so that the temperature of the wafer W increases up to, for example, about 150° C. to 500° C., desirably, about 400° C. to 500° C. Then, the valves V1 to V4 are opened. Herein, though the gas supply lines 63 and 64 are described to be opened or closed individually by the valves V1 to V4 for the simplicity of explanation, an actual gas line system is complicated so that the opening and closing of the gas supply lines 63 and 64 are carried out by stop valves or the like. If the inside of the processing vessel 51 is allowed to communicate with the inside of the reservoir 66 as a result of opening the first gas supply line 63, vapor of formic acid (source gas) in the reservoir 66 is introduced into the gas shower head 61 via the first gas supply line 63, while its flow rate is regulated by the mass flow controller M1.

Meanwhile, an Ar gas as a dilution gas is supplied into the gas shower head 61 from the dilution gas supply source 67 through the second gas supply line 64, while its flow rate is controlled by the mass flow controller M2. In the gas shower head 61, the Ar gas is mixed with the formic acid vapor. This gaseous mixture is supplied into the processing vessel 51 through the gas supply holes 62 of the gas shower head 61 and contacts the wafer W, whereby the CuMn film 81 is annealed, as shown in FIG. 5B. At this time, an internal processing pressure of the processing vessel 51 is regulated at, for example, from about 0.1 Pa (7.5×10⁻⁴ Torr) to 101.3 KPa (760 Torr).

By the annealing process, a Cu reduction atmosphere by the formic acid is formed around the wafer W, and Mn in the CuMn film 81 is diffused toward a surface portion of the SiO₂ film 74 under the Cu reduction atmosphere. Therefore, as shown in FIG. 6B, the separation of Cu 82 and Mn progresses and Mn diffused to an interface between the CuMn film 81 and the SiO₂ film 74 reacts with SiO₂, thereby forming a MnSiₓO_{y} film 83. The MnSiₓO_{y} film 83 functions as a barrier layer for inhibiting a diffusion of Cu into the SiO₂ film 74 when Cu is buried in the recess portion 75 later. Furthermore, remaining Mn unused from the formation of the MnSiₓO_{y} film 83 included in the CuMn film 81 moves toward the surface side of the CuMn film 81 to be separated from the Cu in the CuMn film 81, and the Mn precipitated to the surface of the CuMn film 81. Mn 84 on the surface of the CuMn film 81 is deemed to be diffused into the atmosphere and removed. As a result, a Cu film 82, which functions as a seed layer for burying Cu in the recess portion 75 in a subsequent process, is formed from the CuMn film 81 (see FIG. 6C). The diffusion of the Mn 84 (or MnOₓ) into the atmosphere is deemed to take place because sublimation of the Mn precipitated to the surface of the CuMn film 81 occurs due to a low concentration thereof.

For example, with the lapse of 30 minutes after the valves V1 to V4 are opened, the valves V1 to V4 are closed, and supplying of the formic acid vapor and the Ar gas and heating of the wafer W are stopped. Thereafter, the gate valve G is opened, and the second transfer mechanism 26 advances into the processing vessel 51. In the meantime, the supporting pins 57 are elevated to convey the wafer W, which has undergone through the formic acid process, onto the second transfer mechanism 27, and the second transfer mechanism 27 then transfers the wafer W to the first transfer mechanism 26 via the load lock chamber 22 or 23. Then, the wafer W is returned back into the carrier 15 by the first transfer mechanism 26.

If each wafer W is returned into the carrier 15, the carrier 15 is transferred to the Mn removing apparatus 11 by the transfer robot 14. In the Mn removing apparatus 11, each wafer is taken out of the carrier 15 and is submerged in a solution containing hydrochloric acid, whereby the Mn 84 is removed, allowing the Cu film 82 to be exposed, as shown in FIGS. 5D and 6D.

In the following, an expression that “a wafer W is conveyed” will be used to simplify explanation, while omitting the process of carrying it in the carrier 15 by the transfer robot 14. After the Mn (MnOₓ) film 84 is removed, the wafer W is conveyed into the electroplating apparatus 12, in which Cu 85 is buried in the recess portion 75. Thereafter, the wafer W is conveyed into the CMP apparatus 13 and processed by a CMP process therein, whereby the Cu 85 overflowed from the recess portion 75, and the Cu film 82 and the MnSiₓO_{y} film 83 on the surface of the wafer W are removed. Accordingly, an upper wiring 86 electrically connected to the underlayer wiring 72 is finally obtained, as illustrated in FIG. 5F.

The semiconductor manufacturing apparatus 2 in accordance with the above-described embodiment forms the MnSiₓO_{y} film 83, which is called as a self-formed barrier film, by separating Cu and Mn in the CuMn film 81 by means of annealing the CuMn film 81 under the formic acid atmosphere. Further, the apparatus 2 precipitates Mn to the surface of the CuMn film 81 and diffuses the precipitated Mn into the atmosphere by sublimating the precipitated Mn. Accordingly, since the Cu film 82, which would serve as the seed layer for burying the wiring in the recess portion 75, is formed from the CuMn film 81 during the reducing action of the formic acid, the Cu film 82 is inhibited from being oxidized during the annealing process. As a result, by using the Cu film 82 as the seed layer, it is possible to suppress an increase of resistance of the wiring 86 formed in the recess portion 75.

Moreover, if Mn remains in the Cu film 82 when forming the Cu film 82 by separating Mn from the CuMn film 81, there is a concern that a wiring resistivity may increase or vary. In accordance with the present embodiment described above, however, the temperature of the annealing-processed wafer W is set to be about 400° C., and, at that temperature, the separation of Mn and its removal from the CuMn film 81 progress sufficiently, as verified from evaluation tests to be described later. Accordingly, an amount of the Mn remaining in the Cu film 82 is reduced, so that a yield reduction of semiconductor devices formed from the wiring 86 can be suppressed.

Furthermore, instead of Mn used in the present embodiment, Ti, Al, Nb, Cr, V, Y, Tc, Re, or the like can be utilized as an additive metal for forming the Cu alloy. Further, though the formic acid is used as the organic acid to carry out the annealing process in the above-described embodiment, other types of acids, for example, carboxylic acid such as acetic acid, organic acid anhydride such as acetic anhydride, or ketones, can be employed instead to achieve the same effects as described in the embodiment as long as they have a reducing power for Cu.

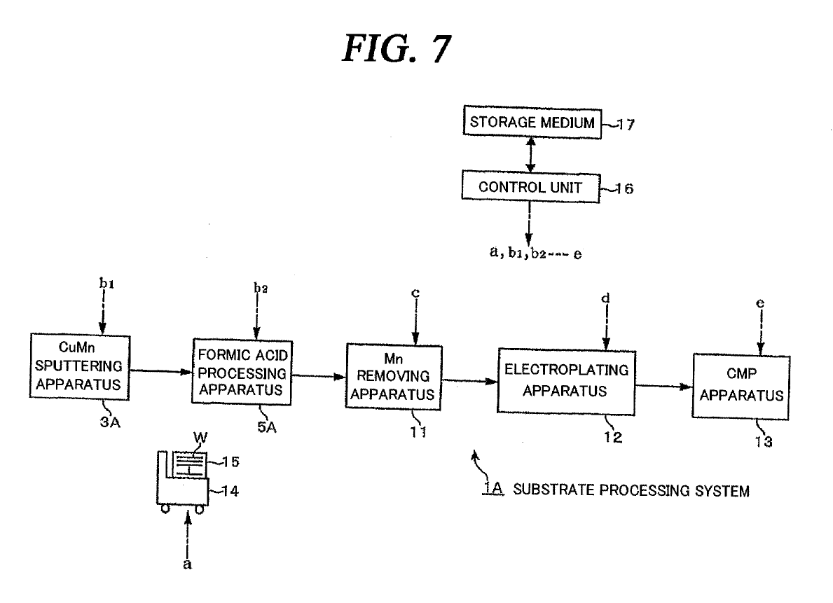

Now, a modification example of the substrate processing system 1 will be described with reference to FIG. 7. A difference of a substrate processing system 1A of FIG. 7 from the substrate processing system 1 is that a CuMn sputtering apparatus 3A and a formic acid processing apparatus 5A, which are controlled by the control unit 16 as like as the semiconductor manufacturing apparatus 2, are installed separately instead of the semiconductor manufacturing apparatus 2. In this example, the CuMn sputtering apparatus 3A, the formic acid processing apparatus 5A and a transfer robot 14 constitute a semiconductor manufacturing apparatus in accordance with an embodiment of the present invention. The sputtering apparatus 3A has the same configuration as that of the sputtering module 3 and the formic acid processing apparatus 5A has the same configuration as that of the formic acid processing module 5 and they performs a film formation process and an annealing process on the wafer W in the same sequence. However, they have their own transfer mechanisms for taking out a wafer W from a carrier 15 and placing the wafer W on their mounting tables 36 and 52, respectively. After a CuMn film 81 is formed on the wafer W by the CuMn sputtering apparatus 3A, the wafer W is conveyed into the formic acid processing apparatus 5A by the transfer robot 14 while being accommodated in the carrier 15 and exposed to an atmospheric atmosphere created therein. Then, after an annealing process on the wafer W is completed in the formic acid processing apparatus 5A, the wafer W is conveyed in the same route as that in the substrate processing system 1, so that an upper wiring 86 is obtained.

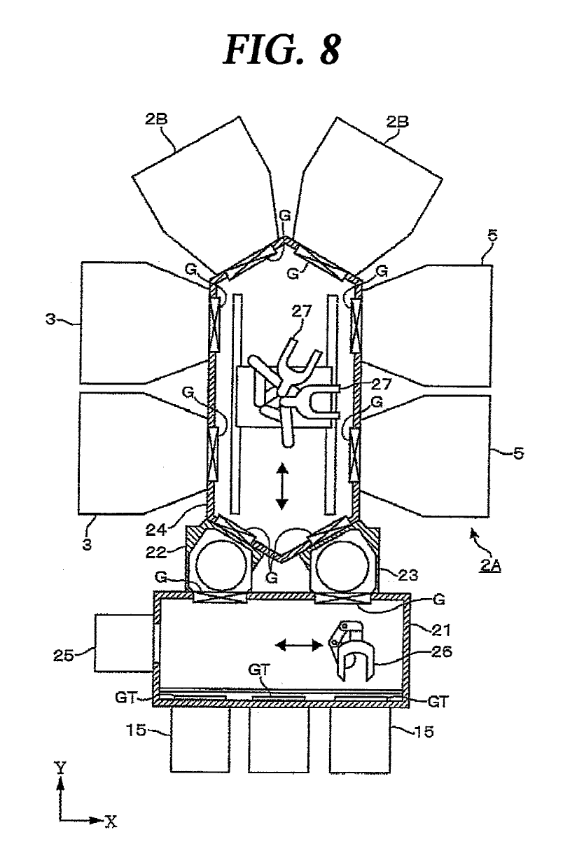

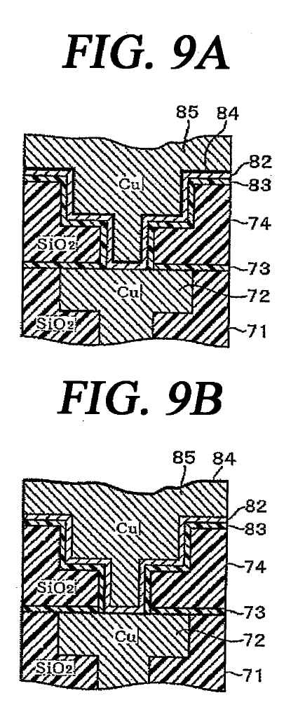

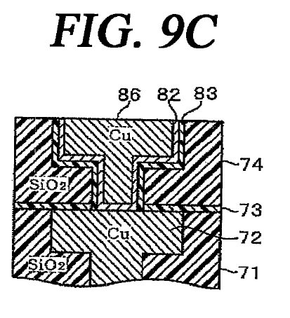

FIG. 8 illustrates another example of semiconductor manufacturing apparatus 2A. The substrate processing apparatus 2A is different from the semiconductor manufacturing apparatus 2 in that Cu CVD (Chemical Vapor Deposition) modules 2B are connected to a second transfer chamber in addition to CuMn sputtering modules 3 and formic acid processing modules 5. In this apparatus 2A, a wafer W is conveyed from one of the CuMn sputtering modules 3 to one of the formic acid processing modules 5, from the formic acid processing module 5 to one of the Cu CVD modules 2B, and, then, from the Cu CVD module 2B to one of the formic acid processing modules 5 in sequence. FIGS. 9A to 9C illustrate a process of forming a wiring performed by the semiconductor manufacturing apparatus 2A. As for the wafer W, which has undergone through the same processes as in the above-described embodiment in the CuMn sputtering module 3 and the formic acid processing module 5, Cu 85 is buried in a recess portion 75 by the Cu CVD module 2B, as shown in FIG. 9A. Subsequently, the wafer W is loaded into the formic acid processing module 5, in which vapor of formic acid is supplied and the wafer W is annealed, whereby Mn 84 is separated from the Cu 85 and precipitated on the surface of the Cu 85, as illustrated in FIG. 9B. Thereafter, the wafer W is conveyed from the semiconductor manufacturing apparatus 2A to a CMP apparatus 13, in which a CMP process is performed on the wafer W and, thus, an upper wiring 86 is formed (see FIG. 9C).

Further, the filing of the recess portion 75 with Cu can also be accomplished by a PVD (Physical Vapor Deposition) method such as sputtering, in addition to the electroplating method or the CVD method mentioned above. Moreover, the method for forming the CuMn film 81 is not limited to the sputtering method, and a CVD method or the like can be employed instead. Furthermore, though each of the sputtering modules 3 and the formic acid processing modules 5 of the semiconductor manufacturing apparatus 2 in accordance with the aforementioned embodiment is described to be of a single-sheet type that processes wafers W sheet by sheet, they can be of a batch type that performs a process on plural wafers at once.

(Evaluation Test 1)

First, samples 1-1 to 1-5 were prepared by forming a CuMn film having a thickness of about 0.05 μm on each of a plurality of wafers W made of SiO₂ in the same sequence as descried in the aforementioned embodiment by using the CuMn sputtering apparatus 3A. After the film formation, the samples 1-1 to 1-4 were conveyed into the formic acid processing apparatus 5A which is kept under an atmospheric atmosphere, and an annealing process was performed on each sample while supplying vapor of formic acid in the same process sequence as described in the aforementioned embodiment. Thereafter, a Mn concentration was measured for every depth of each sample by using a secondary ion mass spectrometer (SIMS). The CuMn target 46 of the sputtering apparatus 3A is made of Cu mixed with 2 atomic percent of Mn. Further, during the annealing process, the internal pressure of the processing vessel 51 of the formic acid processing apparatus 5 was set to be about 133.3 Pa (1 Torr), and a processing time was set to be about 30 minutes. For the annealing process, the samples 1-1 to 1-4 were set to be heated up to about 100° C., 200° C., 300° C. and 400° C., respectively. In addition, the sample 1-5 was exposed to an atmospheric atmosphere after a CuMn film is formed thereon, and a Mn concentration was measured for each depth thereof, as in the case of the samples 1-1 to 1-4.

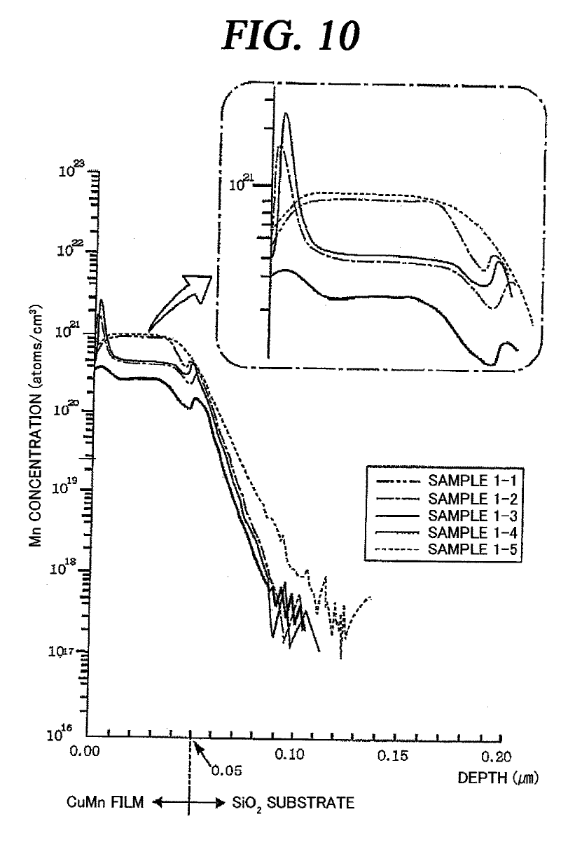

A graph of FIG. 10 shows such measurement results. Results of the samples 1-1 to 1-5 were indicated by a double-dotted dashed line, a single-dotted dashed line, a thin solid line, a thick solid line and a dotted line, respectively. As can be seen from the graph, a Mn concentration distribution of the sample 1-1 is substantially identical with a Mn concentration distribution of the sample 1-5 in a depth range of about 0 μm to 0.05 μm. Further, though the result of the sample 1-1 reveals no movement of Mn triggered by the annealing process, peaks of Mn concentration, which is found near surface portions of the CuMn films in case of the samples 1-2 and 1-3, indicates that Mn was moved by the annealing process in the samples 1-2 and 1-3.

Furthermore, as for the sample 1-4, a Mn concentration in the depth range of 0 μm to 0.05 μm is lower than those of the samples 1-1 to 1-3 and 1-5, while a Mn concentration in a surface side of the CuMn film is higher than a Mn concentration in a substrate side thereof. This result shows that a Mn removing rate of the sample 1-4 is higher than those of the samples 1-2 and 1-3 and this result is deemed to indicate the fact that, as describe above, Mn precipitated on the surface of the CuMn film sublimates and diffuses into the atmosphere with a higher efficiency than those of the samples 1-2 and 1-3. Accordingly, as revealed from the above-described test results, it is desirable to heat the wafer W up to a temperature level higher than about 100° C., for example, about 150° C., to separate Mn from Cu of the CuMn film 81 and, more desirably, up to about 200° C. or higher in order to further facilitate the separation during the annealing process by using an formic acid. In addition, if the wafer W is heated up to about 400° C. or higher, a greater amount of Mn is removed from the CuMn film along with the progression of the separation so that the amount of Mn mixed in a Cu film to be formed from the CuMn film is deemed to decrease. Thus, heating the wafer W to about 400° C. or greater is more desirable. However, to suppress a damage upon each film, it is desirable to set the heating temperature of the wafer W to be no greater than about 500° C.

(Evaluation Test 2)

As in the evaluation test 1, samples 2-1 to 2-6 were prepared by forming CuMn films having a thickness of about 0.05 μm on wafers W made of SiO₂. Unlike in the evaluation test 1, however, the CuMn target 46 of the CuMn sputtering apparatus 3A used to form the CuMn films was formed of Cu mixed with 6 atomic percent of Mn. After the formation of the CuMn films, the samples 2-1 to 2-6 were exposed to the atmosphere, and, then, annealing processes were performed on the samples 2-1 to 2-5 while supplying vapor of formic acid in the same process sequence as described in the aforementioned embodiment. However, the annealing processes of the samples 2-1 to 2-5 were carried out while varying an internal pressure of the processing vessel 51 and a processing time as specified in Table 1 below. A temperature of the wafers W during the annealing processes were set to be about 200° C. in all samples. After the annealing process, a Mn concentration was measured for every depth of each of the samples 2-1 to 2-5 by using the secondary ion mass spectrometer as in the evaluation test 1. As for the sample 2-6, a Mn concentration was measured without performing an annealing process.

TABLE 1

| | Processing pressure | | Processing time | |
|---|---|---|---|---|
| Sample 2-1 | 133.3 | Pa (1 Torr) | 30 | minutes |
| Sample 2-2 | 6.67 | Pa (0.05 Torr) | 30 | minutes |
| Sample 2-3 | 200 | Pa (1.5 Torr) | 30 | minutes |
| Sample 2-4 | 133.3 | Pa (1 Torr) | 5 | minutes |
| Sample 2-5 | 133.3 | Pa (1 Torr) | 3 | hours |

| | | |
|---|---|---|
| Sample 2-6 | — | — |

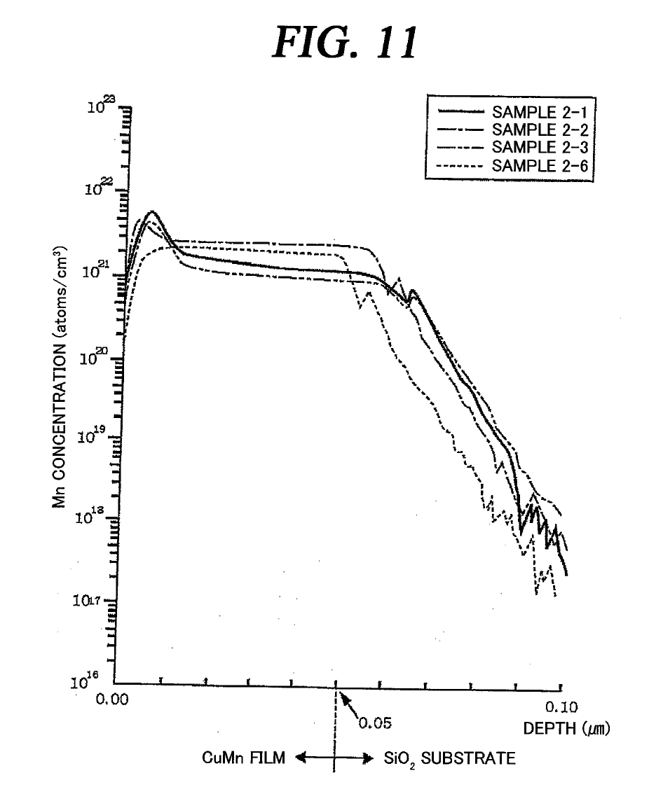

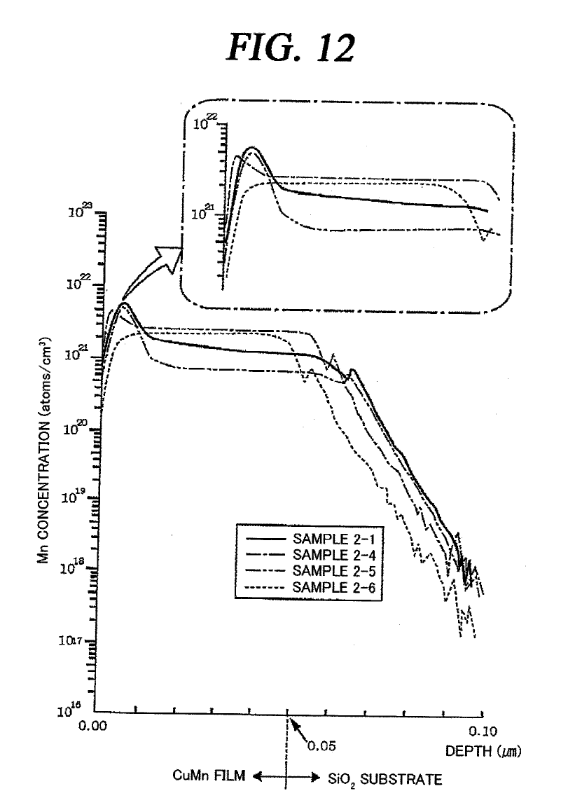

Graphs of FIGS. 11 and 12 show measurement results: FIG. 11 shows measurement results of the samples 2-1 to 2-3 and 2-6, and FIG. 12 shows measurement results of the samples 2-4 to 2-6 and 2-1. In each graph, the results of the samples 2-1 and 2-6 are indicted by a solid line and a dotted line, respectively. In the graph of FIG. 11, the results of the samples 2-2 and 2-3 are indicated by a single-dotted dashed line and a double-dotted dashed line, respectively. In the graph of FIG. 12, the results of the samples 2-4 and 2-5 are indicated by a single-dotted dashed line and a double-dotted dashed line, respectively. In all of the samples 2-1 to 2-3, peaks of Mn concentrations appear near the surfaces of the CuMn films, which reflects the fact that Mn was moved toward the surface sides through the annealing process. In comparison among the samples 2-1 to 2-3, the Mn concentration of the sample 2-3 is lowest between a peak appearing position and a depth of about 0.05 μm. As revealed from this result, it is desirable to set the processing pressure to be high during the annealing process. Moreover, in comparison among the samples 2-1, 2-4 and 2-5, the Mn concentration of the sample 2-5 is lowest, which indicates that it is desirable to increase the processing time since the removed amount of Mn increases with the increasing processing time.

(Evaluation Test 3)

As an evaluation test 3, samples 3-1 to 3-3 were prepared by forming CuMn films having a thickness of about 0.05 μm on wafers W by using the same CuMn target as used in the evaluation test 2. Then, an annealing process was performed on each of the samples 3-1 to 3-3 at about 200° C., 300° C. and 400° C., respectively, by using an acetic anhydride processing apparatus, which has the same configuration as that of the aforementioned formic acid processing apparatus 5A excepting that vapor of acetic anhydride is supplied instead of the vapor of formic acid. In the annealing process of each sample, an internal pressure of the processing vessel 51 of the apparatus and a processing time were set to be about 100 Pa (0.75 Torr) and about 30 minutes, respectively.

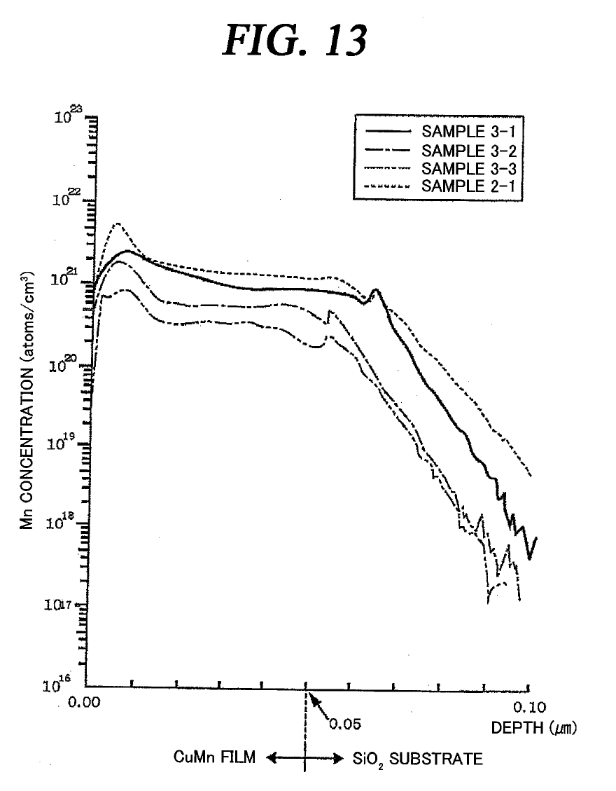

FIG. 13 depicts a graph showing the measurement results, wherein the results of the samples 3-1 to 3-3 were indicated by a solid line, a single-dotted dashed line and a double-dotted dashed line, respectively. Further, the graph of FIG. 13 also shows the result of the sample 2-1 of the Evaluation Test 2 by a dotted line for comparison. As in the sample 2-1, peaks of Mn concentration are observed near the surface of the CuMn films in the samples 3-1 to 3-3, which reveals that a movement of Mn of the CuMn films was made toward the vicinities of the surface sides thereof. In comparison among the samples 3-1 to 3-3, the Mn concentration of the sample 3-3 was the lowest in a depth range from about 0 μm to 0.05 μm, and the Mn concentration of the sample 3-2 was the second lowest. From this comparison, it is revealed that a Mn removing rate improves with an increase of the processing temperature. Accordingly, it is proved that Mn in the CuMn films is moved toward the surfaces of the films even when the acetic anhydride is used, as in the case of using the formic acid, and Mn can be removed more easily as the processing temperature increases.

(Comparative Test) As a comparative test, samples 4-1 and 4-2 were prepared by forming CuMn films having a thickness of about 0.05 μm on wafers W by using the same CuMn target as used in the Evaluation Test 2, and an annealing process was performed on the sample 4-2 at a temperature of about 300° C. by using a nitrogen gas processing apparatus having the same configuration of the above-described formic acid processing apparatus 5A excepting that a nitrogen gas (N₂) was supplied instead of the formic acid. After the annealing process, a Mn concentration was measured for every depth of the sample 4-2 by using the secondary ion mass spectrometer as in the aforementioned evaluation tests. Meanwhile, a Mn concentration of the sample 4-1 was measured without performing an annealing process.

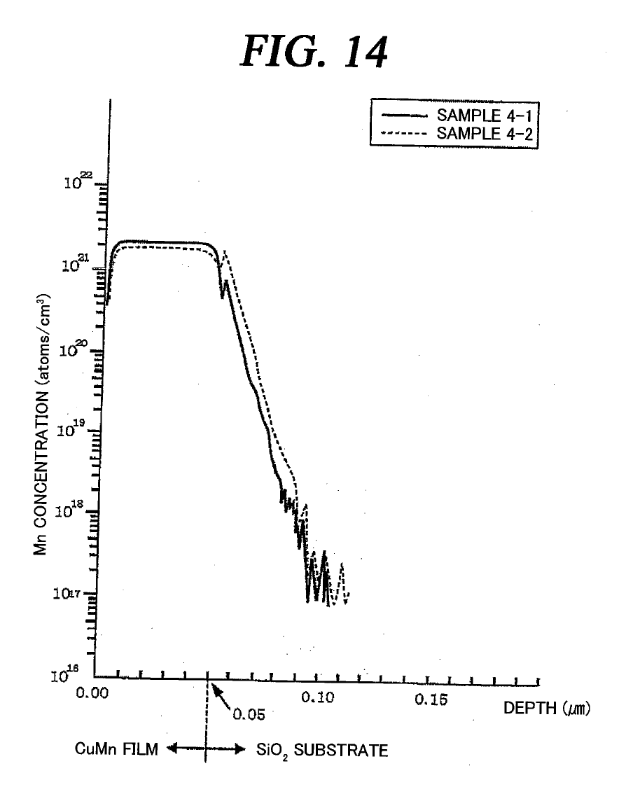

FIG. 14 presents a graph showing the measurement results, wherein the results of the sample 4-1 and the sample 4-2 are indicated by a solid line and a dotted line, respectively. In a depth range of about 0 to 0.05 μm where the CuMn films exist, the samples 4-1 and 4-2 have the substantially same Mn concentrations, and a peak of Mn concentration was not observed near the surfaces of the CuMn films in both cases. From this result, it is revealed that if the CuMn film is heated under the N₂ gas atmosphere, Mn is not moved before and after the heating is performed. Consequently, it is known that Mn does not move under the N₂ gas atmosphere. Accordingly, from the results of the comparative test and the evaluation tests 1 to 3, it is proved that movement of Mn toward the surface side of the CuMn film is facilitated by the influence of the formic acid or acetic anhydride supplied to the wafer W, thus verifying the effect of the present invention.

The above description of the present invention is provided for the purpose of illustration, and it would be understood by those skilled in the art that various changes and modifications may be made without changing technical conception and essential features of the present invention. Thus, it is clear that the above-described embodiments are illustrative in all aspects and do not limit the present invention.

The scope of the present invention is defined by the following claims rather than by the detailed description of the embodiment. It shall be understood that all modifications and embodiments conceived from the meaning and scope of the claims and their equivalents are included in the scope of the present invention.

What is claimed is:

1. A method for manufacturing a semiconductor device, comprising:
forming an alloy film of copper and an additive metal along a wall surface of a recess portion of an interlayer insulating film in a surface of a substrate;
forming a barrier layer made of a compound of the additive metal and a constituent element of the interlayer insulating film;
heating the substrate under an atmosphere containing an organic acid, an organic acid anhydride, or ketones to precipitate surplus additive metal onto a surface of the alloy film; and
burying copper in the recess portion after heating the substrate.

2. The method of claim 1, further comprising, after heating the substrate and before burying the copper, removing the surplus additive metal precipitated on the surface of the alloy film.

3. The method of claim 1, wherein the additive metal is selected from Mn, Ti, Al, Nb, Cr, V, Y, Tc and Re.

4. The method of claim 2, wherein the additive metal is selected from Mn, Ti, Al, Nb, Cr, V, Y, Tc and Re.

5. The method of claim 1, wherein the substrate is heated up to about 200° C. to 500° C. in the step of heating the substrate.

6. The method of claim 2, wherein the substrate is heated up to about 200° C. to 500° C. in the step of heating the substrate.

7. The method of claim 3, wherein the substrate is heated up to about 200° C. to 500° C. in the step of heating the substrate.

8. The method of claim 4, wherein the substrate is heated up to about 200° C. to 500° C. in the step of heating the substrate.

9. The method of claim 5, wherein the substrate is heated up to about 400° C. to 500° C. in the step of heating the substrate.

10. A semiconductor manufacturing apparatus comprising:
a first processing vessel having therein a first mounting table for mounting thereon a substrate in a surface of which an interlayer insulating film provided with a recess portion is formed;
a film forming unit having an alloy film forming mechanism for forming an alloy film of copper and an additive metal along a wall surface of the recess portion;
a second processing vessel having therein a second mounting table for mounting thereon the substrate;
an atmosphere generating unit for generating an atmosphere containing an organic acid, an organic acid anhydride, or ketones in the second processing vessel;
a heating process unit having a heating mechanism for heating the substrate mounted on the second mounting table; and
a substrate transfer mechanism for transferring the substrate between the film forming unit and the heating process unit.

11. The semiconductor manufacturing apparatus of claim 10, further comprising:
a loader module, connected to a carrier accommodating the substrate therein, for performing loading and unloading of the substrate in the carrier; and
a transfer chamber under a vacuum atmosphere, for accommodating the substrate loaded via the loader module,
wherein the first processing vessel and the second processing vessel are airtightly coupled to the transfer chamber, and the transfer mechanism is provided in the transfer chamber.

12. The semiconductor manufacturing apparatus of claim 11, wherein the transfer of the substrate between the film forming unit and the heating process unit is carried out under an atmospheric atmosphere.

13. A storage medium which is used in a semiconductor manufacturing apparatus for performing a process on a substrate and stores therein a computer executable computer program,
wherein the computer program includes step groups for executing the semiconductor device manufacturing method disclosed in claim 1.

14. A storage medium which is used in a semiconductor manufacturing apparatus for performing a process on a substrate and stores therein a computer executable computer program,
wherein the computer program includes step groups for executing the semiconductor device manufacturing method disclosed in claim 2.
